(19) United States
(12) Patent Application Publication
(10) Pub. No.: US 2013/0330846 A1
(43) Pub. Date: Dec. 12, 2013

(54) TEST VEHICLES FOR ENCAPSULATED SEMICONDUCTOR DEVICE PACKAGES

(71) Applicants: Jinbang Tang, Chandler, AZ (US); Daniel M. Boyne, Austin, TX (US)

(72) Inventors: Jinbang Tang, Chandler, AZ (US); Daniel M. Boyne, Austin, TX (US)

(21) Appl. No.: 13/494,160

(22) Filed: Jun. 12, 2012

(51) Int. Cl. H01L 21/66; G01R 31/26

(52) U.S. Cl. 438/15; 324/756.01; 257/E21.531

(57) ABSTRACT

A mechanism to electrically evaluate signals within an encapsulated semiconductor device package without the need for redesigning the package substrate is provided. Test bond pads are provided on a top surface of a semiconductor device die being placed within the semiconductor device package. One or more wire bonds having an elevated loop height are formed on the test bond pads. After encapsulating the semiconductor device package, the package encapsulant is subject to a backgrind process to expose a portion of the test connection wire bonds. Only an amount of the package encapsulant sufficient to expose each test connection wire bond is removed, so that the remaining encapsulant will continue to have the same effect on the package as would be present in a production device. Test probes can then be applied to the exposed test connection wire bonds.

### BACKGROUND

1. Field

This disclosure relates generally to testing of encapsulated semiconductor device packages, and more specifically, to providing a mechanism to probe internal package signals while maintaining package encapsulation and without modification to the package interconnect.

2. Related Art

Modern semiconductor packages include one or more semiconductor devices coupled to a package substrate and encapsulated in a molding compound to protect the aggregate of devices, electrical coupling, and the like. Signal communication between the packaged semiconductor devices, both internal to the package and external to the package, is handled by a package interconnect formed on the package substrate. In high density packaging applications, routing of the signal net provided by the package interconnect can be very complex, requiring significant design resources.

Testing of the aggregated package and the individual components encapsulated within the package is often required to determine whether the package is operating within design specifications. Traditionally, one method of gaining access to signal values within a package involves removing the encapsulant in order to gain access to the individual devices and electrical couplings within the package. A drawback of this method is that the encapsulant itself, which is typically a dielectric material, may affect the signals of interest. Thus, removing the encapsulant changes the electrical characteristics of the package and reduces the value of the test results. To avoid this problem, another method of gaining access to signal values involves providing a test signal net on the package substrate. In this method, the package interconnect must be redesigned in order to accommodate the test signal net. But for high density packaging applications, this redesign requires an even greater expenditure of design resources to accommodate the test signal net. Further, such a modification of the package interconnect may also change the electrical characteristics of the package.

It is therefore desirable to provide a mechanism to electrically evaluate signals within an encapsulated semiconductor device package without the need for redesigning the package substrate.

### BRIEF DESCRIPTION OF THE DRAWINGS

The present invention may be better understood, and its numerous objects, features, and advantages made apparent to those skilled in the art by referencing the accompanying drawings.

FIG. 1 is a simplified block diagram illustrating an example of a cross-section of a prior art test system that includes a semiconductor device package on a test board.

FIG. 2 is a simplified block diagram illustrating a cross-section of a semiconductor device package at a stage of production, in accord with embodiments of the present invention.

FIG. 3 is a simplified perspective diagram illustrating semiconductor device package 200 at the same stage manufacture as provided in FIG. 2.

FIG. 4 is a simplified block diagram of a cross-section of the semiconductor device package at a processing stage subsequent to that of FIG. 2, in accord with embodiments of the present invention.

FIG. 5 is a simplified block diagram of a cross-section of the semiconductor device package at a processing stage subsequent to that of FIG. 4, in accord with embodiments of the present invention.

FIG. 6 is a simplified perspective diagram of the semiconductor device package mounted on a test board subsequent to encapsulation and reduction of encapsulant thickness, in accord with embodiments of the present invention.

FIG. 7 is a simplified perspective diagram of an example force-sense test configuration usable in conjunction with embodiments of the present invention.

FIG. 8 is a simplified perspective diagram illustrating a close up of the connection configuration of FIG. 7.

The use of the same reference symbols in different drawings indicates identical items unless otherwise noted. The figures are not necessarily drawn to scale.

### DETAILED DESCRIPTION

Embodiments of the present invention provide a mechanism to electrically evaluate signals within an encapsulated semiconductor device package without the need for redesigning the package substrate. Test bond pads are provided on a top surface of a semiconductor device die being placed within the semiconductor device package. One or more wire bonds having an elevated loop height are formed on the test bond pads. After encapsulating the semiconductor device package, the package encapsulant is subject to a backgrind process to expose a portion of the test connection wire bonds. Only an amount of the package encapsulant sufficient to expose each test connection wire bond is removed, so that the remaining encapsulant will continue to have the same effect on the package as would be present in a production device. Test probes can then be applied to the exposed test connection wire bonds so that signals of interest can be read or signals can be applied to those connections. In this manner, specific signal connections can be made without redesigning the package substrate.

In a traditional semiconductor device testing environment, a semiconductor device package is mounted on a test board that enables electrical evaluation of accessible signal net contacts. Test probe contacts are provided on the test board to allow for probing of the semiconductor device package signal net during operational conditions, or specific test conditions. A limitation of the typical test board configuration is there is access only to those signals that can be provided through the semiconductor device package substrate interconnect. For high density package interconnect, it is difficult to provide additional signal routing for specific signals of interest within the package.

In the past, the only practical alternative to providing additional signal routing on the package substrate was to remove the encapsulant for the semiconductor device package to gain access to the connections of the individual semiconductor device die and their couplings within the package. A drawback of this method is that by removing the molding compound, any electrical effects the molding compound may have on the semiconductor device package signals are altered. Therefore, an operational assessment of the package signals cannot be acquired.

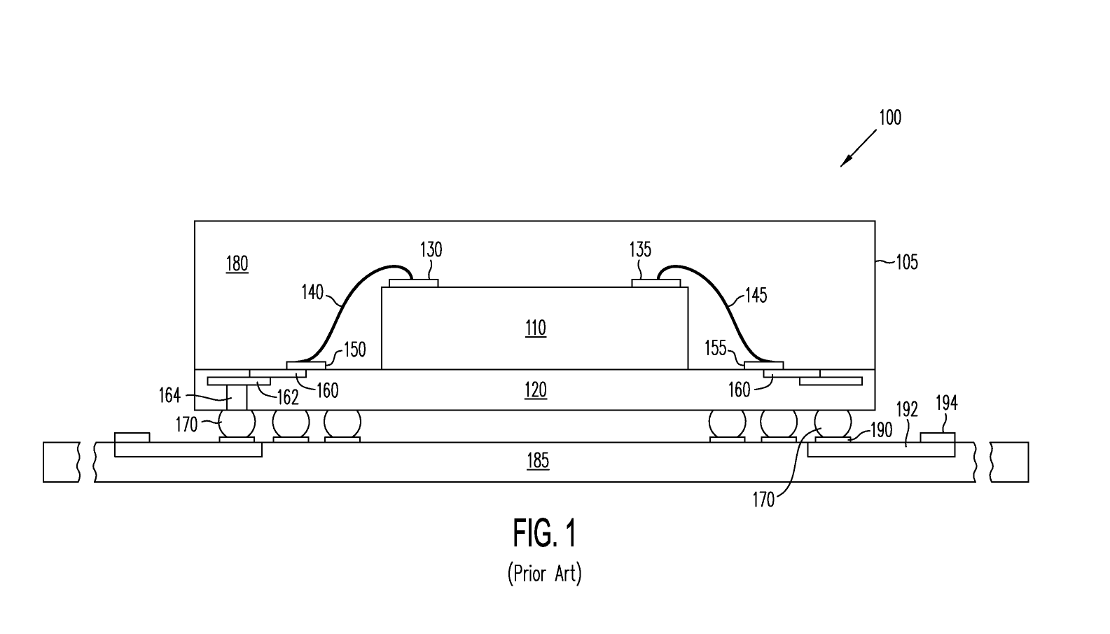

FIG. 1 is a simplified block diagram illustrating an example of a cross-section of a test system 100 that includes a semiconductor device package 105 on a test board 185. A semiconductor device die 110 is coupled to a package substrate 120. One or more electrical contact pads 130 and 135 are provided on a free surface of a semiconductor device die 110. Wire bonds 140 and 145 electrically couple electrical contact pads 130 and 135, respectively, to substrate contacts 150 and 155, respectively. In turn, the substrate contacts are electrically coupled to a substrate interconnect formed by metal layers 160 and 162, as well as vias 164 that couple the substrate interconnect to package external contacts 170 (e.g., ball tips and the like).

Semiconductor device package 105 is encapsulated in encapsulant 180. A molding material is applied to the structures affixed to package substrate 120 (e.g., semiconductor device die 110, wire bonds 140 and 145, and the like), forming an encapsulant 180 that encapsulates the structures within the molding material. The molding material includes any appropriate material, including, for example, silica-filled epoxy molding compounds, plastic encapsulation resins, and other polymeric materials such as silicones, polyimides, phenolics, and polyurethanes. The molding material can be applied by a variety of standard processing techniques used in encapsulation including, for example, printing, pressure molding and spin application. In a typical encapsulation process, a depth of encapsulant 180 exceeds a maximum height of structures embedded in the molding material (e.g., the height of wire bond 140 and 145).

In the test environment, semiconductor device package 105 is electrically coupled to test board 185 using, for example, a test board electrical contact 190 in contact with package external contact 170. Test board electrical contact 190 is coupled to test board contact 194 via test board interconnect 192.

Electrical signals can be applied to semiconductor device die 110 via test board contact 194, or read from the semiconductor device die using test board contact 194. Through concurrent use of several test board contacts, a variety of electrical test conditions can be examined. But, as discussed above, this structure only provides for testing of signals that can be brought through the semiconductor device package substrate, which may be limited by the density of the package signal net.

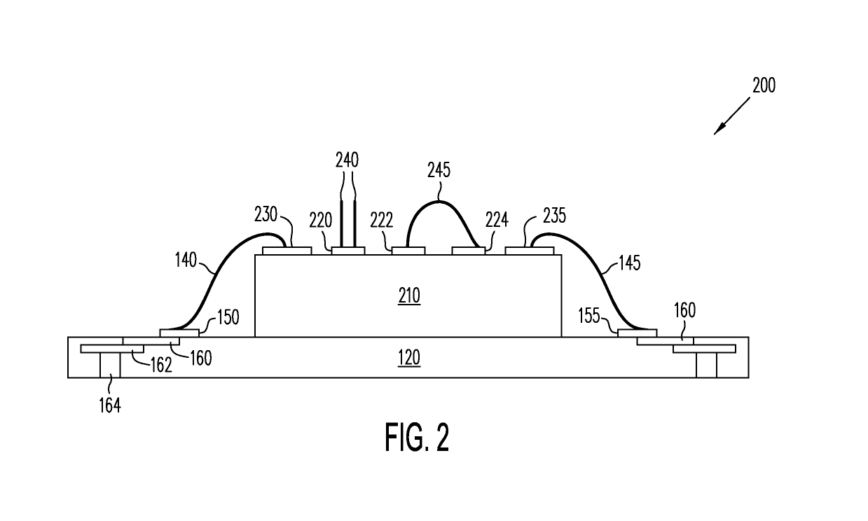

FIG. 2 is a simplified block diagram illustrating a cross-section of a semiconductor device package 200 at a stage of production, in accord with embodiments of the present invention. Package substrate 120 from FIG. 1 is shown in FIG. 2, including substrate contacts 150 and 155 and interconnect portions 160, 162, and 164. This indicates that no changes (or minimal changes) need to be made to the package substrate to allow for the test signal connections provided by embodiments of the present invention.

Semiconductor device die 210 is a modified version of semiconductor device die 110 that includes, for example, test contacts 220, 222, and 224 on the top surface of the semiconductor device die. Test contacts 220, 222, and 224 can be electrically coupled to portions of the circuitry within semiconductor device die 210 that are generating signals of interest for a test. Thus, semiconductor device die 210 is modified to provide electrical conduits to the test contacts. Semiconductor device die 210 also includes electrical contact pads 230 and 235, which correspond to electrical contact pads 130 and 135, respectively, from FIG. 1.

Test contacts 220, 222, and 224 are not directly accessible when the semiconductor device package that incorporates semiconductor device die 210 is encapsulated, since the test contacts will be covered by encapsulant. To enable such a contact, and elaborated on below, test wire bonds 240 and 245, for example, are electrically coupled to the test contacts. One feature of test wire bonds 240 and 245 is that they extend to a height above the top surface of semiconductor device die 210 that is greater than the height of any non-test wire bonds coupled to contacts on the semiconductor device die (e.g., wire bonds 140 and 145). As discussed below, this additional height of the test wire bond enables access to contacts created by those test wire bonds without disturbing the non-test wire bonds.

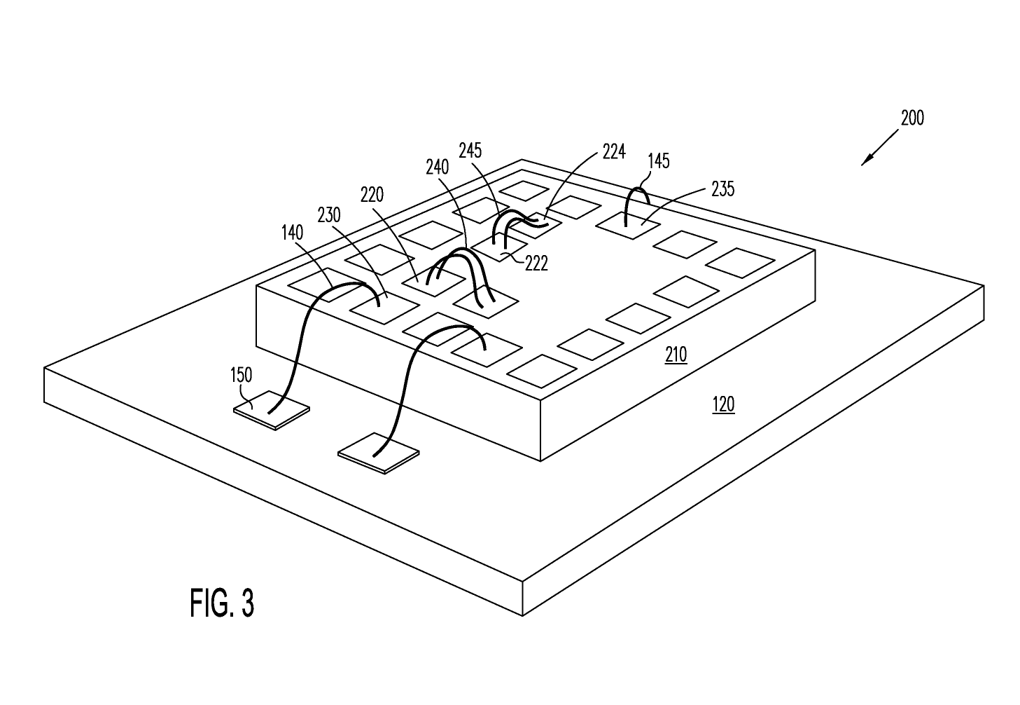

FIG. 3 is a simplified perspective diagram illustrating semiconductor device package 200 at the same stage manufacture as provided in FIG. 2. Test wire bonds 240 and 245 are illustrated as a pair of wire bonds associated with test contact pairs (e.g., 222 and 224), but embodiments of the present invention are not limited to such a structure. For example, a single test wire bond can connect a test contact pair, or test wire bonds can be associated with a single test contact (e.g., attached to the test contact and then drawn vertical to the test contact surface and cut). The test contact pair can include a dummy contact to provide a connection point for the test wire bond, or two active test contacts. The test wire bonds can be made from a variety of materials appropriate to the application, including, for example, gold and copper.

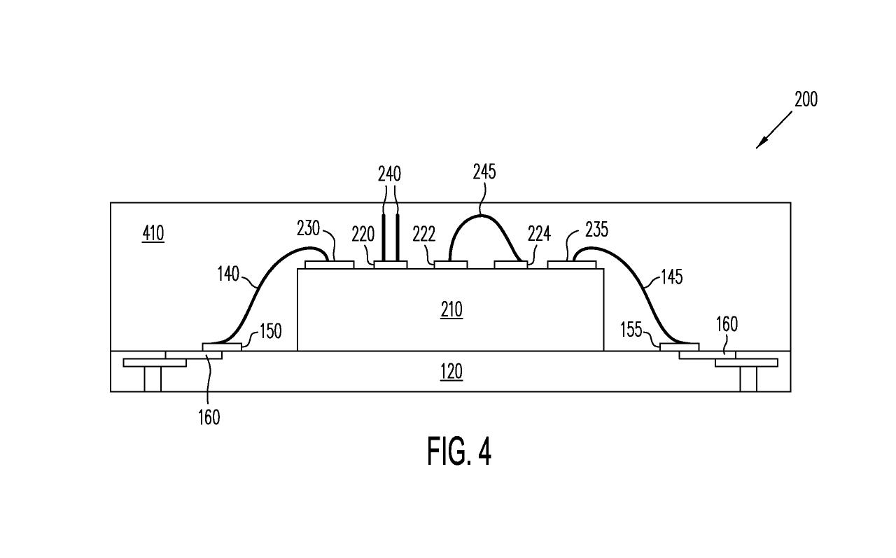

FIG. 4 is a simplified block diagram of a cross-section of semiconductor device package 200 at a processing stage subsequent to that of FIG. 2, in accord with embodiments of the present invention. In FIG. 4, semiconductor device package 200 is encapsulated in encapsulant 410. A molding material is applied to the structures affixed to package substrate 120 (e.g., semiconductor device die 210, wire bonds 140 and 145, test wire bonds 240 and 245, and the like), forming encapsulant 410 that encapsulates the structures within the molding material. The molding compound materials can be the same as those described above with regard to FIG. 1, and reflect the molding compounds to be used for a production package corresponding to semiconductor device package 200.

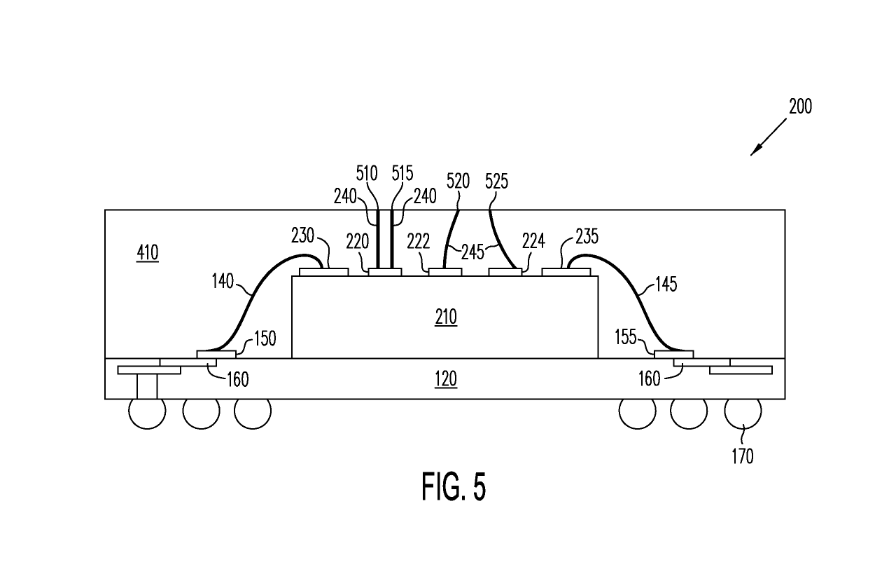

FIG. 5 is a simplified block diagram of a cross-section of semiconductor device package 200 at a processing stage subsequent to that of FIG. 4, in accord with embodiments of the present invention. In FIG. 5, after encapsulant 410 has been cured and hardened, the encapsulant is reduced in thickness to expose a portion of test wire bonds 240 and 245. Exposing the portions of test wire bonds 240 and 245 provides contacts 510 and 515 (associated with test wire bond 240) and 520 and 525 (associated with test wire bond 245). As discussed above, test wire bonds 240 and 245 are drawn to a height greater than that of any non-test wire bonds provided from semiconductor device die 210, thereby enabling the test wire bonds to be exposed without disturbing the non-test wire bonds.

Reducing the thickness of encapsulant 410 can be performed by a variety of methods appropriate to the application. For example, the encapsulated package can be subjected to a mechanical polishing process for a backgrind of the encapsulant to below the height of all the test wire bonds associated with a semiconductor device package. Alternatively, the encapsulated package can be subjected to a laser ablation process to reduce the thickness of encapsulant 410. It should be understood that embodiments of the present invention are not limited to the mechanism by which the semiconductor device package encapsulant is reduced in thickness. Further, test wire bonds of varying heights above semiconductor device die within a package can be provided. In such an application, the depth of the encapsulant thickness reduction can be varied to expose only those test wire bond contacts of interest for a particular test.

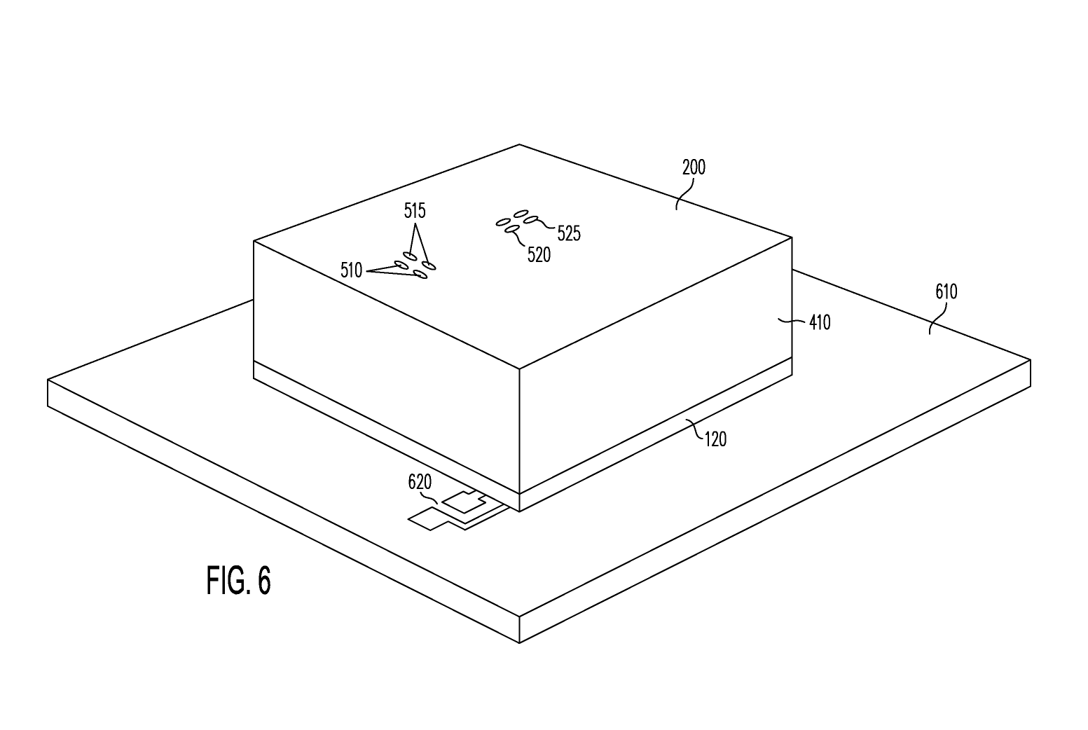

FIG. 6 is a simplified perspective diagram of a semiconductor device package 200 mounted on a test board 610 subsequent to encapsulation and reduction of encapsulant thickness, in accord with embodiments of the present invention. As illustrated, additional tests contacts 510, 515, 520, and 525 are exposed on the top surface of semiconductor device package 200. Test board 610 is also illustrated with an example test contact 620 that provides access to the semiconductor device package signal net, as discussed above with regard to test board contact 194. Test contact 620 is one of a plurality of test contacts that can be provided on a test board 610, which are not shown.

The area of test contacts 510, 515, 520, and 525 corresponds to a cross-section of the test wire bonds and the depth of the reduced thickness encapsulant. A typical diameter of the test wire bonds can be between 15 to 30 microns. Should the exposed cross-sectional area be insufficient to allow for a good contact with a test probe, a larger test probe pad can be formed on the surface of semiconductor device package 200 in electrical contact with the exposed wire bond, using standard techniques.

As discussed above, providing test contacts such as 510, 515, 520, and 525 allows for performing electrical evaluation of devices within a semiconductor device package while maintaining encapsulant over the devices within the package. This can be important in situations where the mold compound forming the encapsulant material may alter the electrical characteristics of devices and wire bonds within the semiconductor device package. For example, electromigration effects in wire bonds or other electrical contacts may be enhanced in an encapsulant and it would be desirable to determine the extent of these effects in a device under test.

Embodiments of the present invention provide capacity to conduct a variety of tests on a semiconductor device package under test. For example, contacts can be provided to allow a four-point Kelvin test, also known as a force-sense test, to be conducted. In such a test environment, contacts for voltage measurement and current provision can be made on the device package.

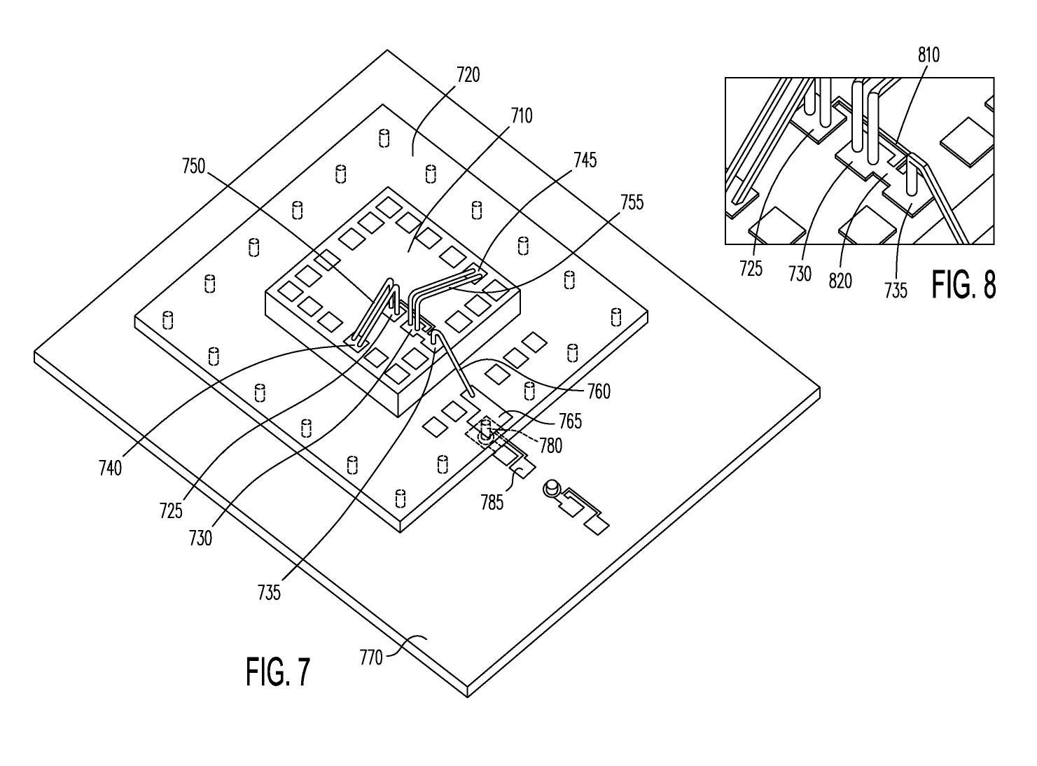

FIG. 7 is a simplified perspective diagram of an example force-sense test configuration, in conjunction with embodiments of the present invention. A semiconductor device die 710 is mounted on a semiconductor device package substrate 720. Semiconductor device die 710 has a number of contact pads on a top surface, including test contacts 725 and 730. Test contact 730 is electrically connected to a dummy contact 745 by test wire bonds 755. Test contact 725 is electrically connected to a dummy contact 740 by test wire bonds 750. Contact 735 is electrically connected to a substrate contact 765 by a wire bond 760. Test contacts 725 and 730 and contact 735 are electrically coupled to permit a force-sense test. In addition, substrate 720 is electrically coupled to test board 770 by, for example, a package contacts 780, which can take the form of a ball conductor, copper stud, and the like. As illustrated, contact 780 is electrically coupled to test board contact 785. In this manner, the test contacts on semiconductor device die 710 can be electrically coupled to test board contacts. Using these test contacts, a four-point Kelvin test can be performed to measure resistance from, for example, die contact 735 to package contact 780.

FIG. 8 is a simplified perspective diagram illustrating a close up of the connection configuration of test contacts 725 and 730 and contact 735. Metal plating 820 electrically couples test contact 730 with contact pad 735, while metal plating 810 electrically couples test contact 725 with both test contact 730 and contact 735. Through the use of this electrical coupling, a current can be applied to test contact 730 via test wire bond 755. Similarly, test wire bond 750 can be used to measure the voltage at test contact 725. These contacts can be used to determine resistance and electromigration effects in, for example, the electrical path between contact pad 735 and package contact 780, including wire bond 760 and contact 735.

By now it should be appreciated that there has been provided a method for testing electrical characteristics of a semiconductor device package. The method includes coupling a first major surface of a semiconductor device to a major surface of a semiconductor device package substrate, where the semiconductor device includes a first set of test contacts on a second major surface of the semiconductor device and a second set of signal net contacts on the second major surface of the semiconductor device and the second major surface opposes the first major surface of the semiconductor device. The method further includes: forming a first wire bond from one of the signal net contacts to a contact on the semiconductor device package substrate; forming a first test wire bond on one or more the test contacts in which an apex of the first test wire bond is elevated higher from the second major surface of the semiconductor device than an apex of the first wire bond; encapsulating the semiconductor device package substrate, exposed sides of the semiconductor device, the first wire bond, and the first test wire bond using an encapsulant in order to form the semiconductor device package; and, removing a portion of the encapsulant from the semiconductor device package where the removing exposes a portion of the first test wire bond and does not expose the first wire bond.

One aspect of the above embodiment further includes testing and electrical characteristic of the semiconductor device package using the exposed portion of the first test wire bond. In a further aspect, the testing further includes contacting the exposed portion of the first test wire bond with a test probe. Another further aspect includes forming a test probe contacts on a surface of the semiconductor device package, electrically coupling the test probe contact with the exposed portion of the first test wire bond, and performing the testing by contacting the test probe contact with a test probe. Another further aspect provides for performing the testing of the electrical characteristic without modification of an interconnect formed on the substrate.

Another aspect of the above embodiment further includes forming a second test wire bond on one or more of the test contacts where an apex of the second test wire bond is elevated higher than an apex of the first wire bond above the second major surface of the semiconductor device, and removing the portion of the encapsulant further includes exposing a portion of the second test wire bond. A further aspect includes testing one or more electrical characteristics of the semiconductor device package using the exposed portions of the first and second test wire bonds. In still a further aspect, testing one or more electrical characteristics of the semiconductor device package is performed using exposed portions of the first and second test wire bonds. In yet a further aspect, the testing of the one or more electrical characteristics of the semiconductor device package includes performing a four-point probe.

Another aspect of the above embodiment provides for removing the portion of the encapsulant by performing a backgrind operation to a depth sufficient to expose the first test wire bond. A further aspect provides that the backgrind operation is a polishing operation.

Another embodiment of the present invention provides a system that includes a semiconductor device package and a test stand for testing the semiconductor device package. The semiconductor device package includes one or more semiconductor device die encapsulated in an encapsulant, a first set of electrical contacts external to the encapsulant and coupled to a first signal net of the semiconductor device package, a second set of electrical contacts external to the encapsulant then coupled to a second signal net of the semiconductor device package where the second set of electrical contacts are disposed on a first major surface of the semiconductor device package, and a first semiconductor device die of the one or more semiconductor device die that includes a set of test contacts on a major surface of the first semiconductor device die where the set of test contacts are electrically coupled to corresponding contacts of the second set of electrical contacts via corresponding wire bonds. The test stand includes a first set of contacts electrically coupled to the first of electrical contacts of the semiconductor device package and a second set of contacts electrically coupled to the second set of electrical contacts of the semiconductor device package.

In one aspect of the above embodiment, the second signal net of the semiconductor device package is a test signal net. In another aspect of the above embodiment, the semiconductor device package further includes a package substrate where the package substrate includes the first signal net and the first set of electrical contacts, the first signal net is electrically coupled to the one or more semiconductor device die, and at least a portion of the package substrate is encapsulated in the encapsulant. In a further aspect, the system is configured to electrically test the semiconductor device package without exposing a portion of the one or more semiconductor device die in order to provide a test contact.

Another aspect of the above embodiment provides for the second set of contacts to be coupled to the second set of electrical contacts of the semiconductor device package in order to perform a four-point Kelvin test on connections within the semiconductor device package.

Because the apparatus implementing the present invention is, for the most part, composed of electronic components and circuits known to those skilled in the art, circuit details will not be explained in any greater extent than that considered necessary as illustrated above, for the understanding and appreciation of the underlying concepts of the present invention and in order not to obfuscate or distract from the teachings of the present invention.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

The illustrated elements of systems 100 and 200 are circuitry located on a single integrated circuit or within a same device. Alternatively, these systems may include any number of separate devices interconnected with each other.

Although the invention is described herein with reference to specific embodiments, various modifications and changes can be made without departing from the scope of the present invention as set forth in the claims below. For example, there are a variety of methods for reducing the thickness of encapsulant on a package. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A method for testing electrical characteristics of a semiconductor device package, the method comprising:
coupling a first major surface of a semiconductor device to a major surface of a semiconductor device package substrate, wherein
the semiconductor device comprises a first set of test contacts on a second major surface of the semiconductor device and a second set of signal net contacts on the second major surface of the semiconductor device, and
the second major surface opposes the first major surface of the semiconductor device;
forming a first wire bond from one of the signal net contacts to a contact on the semiconductor device package substrate;
forming a first test wire bond on one or more of the test contacts, wherein an apex of the first test wire bond is elevated higher from the second major surface of the semiconductor device than an apex of the first wire bond;
encapsulating the semiconductor device package substrate, exposed sides of the semiconductor device, the first wire bond, and the first test wire bond using an encapsulant in order to form the semiconductor device package; and
removing a portion of the encapsulant from the semiconductor device package, wherein said removing exposes a portion of the first test wire bond and does not expose the first wire bond.

2. The method of claim 1 further comprising:
testing an electrical characteristic of the semiconductor device package using the exposed portion of the first test wire bond.

3. The method of claim 2 further comprising:
performing said testing further comprises contacting the exposed portion of the first test wire bond with a test probe.

4. The method of claim 2 further comprising:
forming a test probe contact on a surface of the semiconductor device package;
electrically coupling the test probe contact with the exposed portion of the first test wire bond; and
performing said testing further comprises contacting the test probe contact with a test probe.

5. The method of claim 2 wherein said testing the electrical characteristic is performed without modification of an interconnect formed on the substrate.

6. The method of claim 1 further comprising:
forming a second test wire bond on one or more of the test contacts, wherein
an apex of the second test wire bond is elevated higher than an apex of the first wire bond above the second major surface of the semiconductor device; and
said removing the portion of the encapsulant further exposes a portion of the second test wire bond.

7. The method of claim 6 further comprising:
testing one or more electrical characteristics of the semiconductor device package using the exposed portions of the first and second test wire bonds.

8. The method of claim 7 wherein said testing the one or more electrical characteristics of the semiconductor device package comprises performing a four-point probe.

9. The method of claim 1 wherein said removing the portion of the encapsulant comprises:
performing a backgrind operation to a depth sufficient to expose the first test wire bond.

10. The method of claim 9 wherein said backgrind operation is a polishing operation.

11. A system comprising:
a semiconductor device package comprising
one or more semiconductor device die encapsulated in an encapsulant,
a first set of electrical contacts external to the encapsulant and coupled to a first signal net of the semiconductor device package,
a second set of electrical contacts external to the encapsulant and coupled to a second signal net of the semiconductor device package, wherein the second set of electrical contacts are disposed on a first major surface of the semiconductor device package, and
a first semiconductor device die of the one or more semiconductor device die that comprises a set of test contacts on a major surface of the first semiconductor device die, wherein the set of test contacts are electrically coupled to corresponding contacts of the second set of electrical contacts via corresponding wire bonds; and
a test stand comprising a first set of contacts electrically coupled to the first set of electrical contacts of the semiconductor device package and a second set of contacts electrically coupled to the second set of electrical contacts of the semiconductor device package.

12. The system of claim 11 wherein the second signal net of the semiconductor device package is a test signal net.

13. The system of claim 11 further comprising:
the semiconductor device package further comprising a package substrate, wherein
the package substrate comprises the first signal net and the first set of electrical contacts,
the first signal net is electrically coupled to the one or more semiconductor device die, and
at least a portion of the package substrate is encapsulated in the encapsulant.

14. The system of claim 13, wherein the system is configured to electrically test the semiconductor device package without exposing a portion of the one or more semiconductor device die to provide a test contact.

15. The system of claim 11 wherein the second set of contacts are coupled to the second set of electrical contacts of the semiconductor device package to perform a four-point Kelvin test on connections within the semiconductor device package.
